(19) United States
(12) Patent Application Publication
(10) Pub. No.: US 2026/0096347 A1
(43) Pub. Date: Apr. 2, 2026

(54) PIEZOELECTRIC ELEMENT AND LIQUID EJECTION HEAD

(71) Applicant: SEIKO EPSON CORPORATION, Tokyo (JP)

(72) Inventors: Nobuo OZAWA, CHINO-SHI (JP); Takatoshi YAMAZAKI, SHIOJIRI-SHI (JP); Toshihiro SHIMIZU, FUJIMI-MACHI (JP); Shunsuke YOSHIDA, MATSUMOTO-SHI (JP)

(21) Appl. No.: 19/342,946

(22) Filed: Sep. 29, 2025

(30) Foreign Application Priority Data
Sep. 30, 2024 (JP) 2024-170717

(51) Int. Cl. H10N 30/00; B41J 2/14; B41J 2/16; H10N 30/50; H10N 30/853; H10N 30/87; H10N 30/88

(52) U.S. Cl. CPC H10N 30/708; B41J 2/14233; B41J 2/161; H10N 30/501; H10N 30/8554; H10N 30/872; H10N 30/883; B41J 2002/14258

(57) ABSTRACT

In a piezoelectric element in which a lower electrode, a piezoelectric layer formed of a perovskite-type complex oxide, and an upper electrode are laminated in a laminating direction, the upper electrode has a first hydrogen absorbing layer that absorbs hydrogen. The upper electrode of the piezoelectric element preferably has a second hydrogen absorbing layer different from the first hydrogen absorbing layer. In the piezoelectric element, the film thickness of the first hydrogen absorbing layer is preferably thicker than the film thickness of the second hydrogen absorbing layer in the laminating direction.

The present application is based on, and claims priority from JP Application Serial Number 2024-170717, filed Sep. 30, 2024, the disclosure of which is hereby incorporated by reference herein in its entirety.

### BACKGROUND

### 1. Technical Field

The present disclosure relates to a piezoelectric element and a liquid ejection head.

### 2. Related Art

Image forming devices provided with liquid ejection heads that eject liquids such as inks onto a medium such as printing paper were proposed in the related art. As such a liquid ejection head, a head is known that ejects liquid filled in a pressure chamber from a nozzle by vibrating a vibration plate that forms the wall surface of the pressure chamber using a piezoelectric element.

The piezoelectric element of the liquid ejection head described in JP-A-2010-214800 has a pair of electrodes and a piezoelectric layer interposed between the pair of electrodes. The piezoelectric layer has a perovskite structure, such as PZT.

The piezoelectric layer described in JP-A-2010-214800 is formed of a plurality of layers formed by the sol-gel method. Each of the plurality of layers is formed by coating and drying a coating solution including an organic compound to form a gelled precursor film and then firing the precursor film. The film-forming and firing of this precursor film are repeated a plurality of times to form a piezoelectric layer formed of a plurality of layers.

In this piezoelectric element, a composition gradient is known to occur in each layer depending on the crystallization temperature of the material. For example, when the piezoelectric layer is lead zirconate titanate, titanium is likely to segregate in large amounts at the interface where crystallization tends to proceed quickly due to the difference in crystallization temperature between lead titanate and lead zirconate. For this reason, the composition of each layer may differ between the vicinity of the interface and the center of the layer. When such a composition gradient occurs, there is a concern that the displacement characteristics of the piezoelectric element may be affected.

In addition, as the result of extensive research, the present inventors also found that the hysteresis characteristics change significantly depending on the hydrogen content of the piezoelectric layer. In particular, it was found that, even when the composition gradient of the piezoelectric element is uniform, the hysteresis characteristics change depending on the hydrogen content. In addition, hydrogen had a strong tendency to enter the piezoelectric layer from the outside.

The amounts of displacement differ for each piezoelectric element when the hysteresis characteristics of the piezoelectric elements change. For this reason, it is necessary to adjust the difference by changing the driving voltage or waveform for each piezoelectric element. Thus, there is a problem in that the usability is poor.

### SUMMARY

According to an aspect of the present disclosure, there is provided a piezoelectric element including a lower electrode, a piezoelectric layer formed of a perovskite-type complex oxide, and an upper electrode having a first hydrogen absorbing layer, in which the lower electrode, the piezoelectric layer, and the upper electrode are laminated in a laminating direction, and the upper electrode has a first hydrogen absorbing layer that absorbs hydrogen.

According to another aspect of the present disclosure, there is provided a liquid ejection head having a piezoelectric element.

### BRIEF DESCRIPTION OF THE DRAWINGS

FIG. 1 is a schematic diagram illustrating a configuration of an image forming device according to a first embodiment.

FIG. 2 is an exploded perspective diagram of a liquid ejection head shown in FIG. 1.

FIG. 3 is a cross-sectional diagram of a part of a liquid ejection head shown in FIG. 1.

FIG. 4 is a cross-sectional diagram of the piezoelectric element shown in FIG. 3.

FIG. 5 is a cross-sectional diagram of the piezoelectric element shown in FIG. 3.

FIG. 6 is a diagram schematically showing the piezoelectric element shown in FIG. 4.

FIG. 7 is a diagram showing the measurement results of the piezoelectric element shown in FIG. 6 using a secondary ion mass spectrometer (SIMS).

FIG. 8 is a diagram showing the flow of a method for manufacturing the piezoelectric element in FIG. 6.

FIG. 9 is a diagram schematically showing a piezoelectric element of a first modified example.

FIG. 10 is a diagram schematically showing a piezoelectric element of a second modified example.

FIG. 11 is a cross-sectional diagram of a piezoelectric element of a third modified example.

FIG. 12 is a diagram showing the measurement results of the piezoelectric element of the third modified example using a secondary ion mass spectrometer.

FIG. 13 is a diagram schematically showing a piezoelectric element of a fourth modified example.

### DESCRIPTION OF EMBODIMENTS

A description will be given below of preferred embodiments according to the present disclosure with reference to the attached drawings. The dimensions or scale of each part in the drawings may differ from actual dimensions or scale as appropriate and some portions are shown schematically for ease of understanding. In addition, the scope of the present disclosure is not limited to these forms unless specifically described in the following description to limit the present disclosure. In addition, “element p on element y” is not limited to configurations in which element y and element p are in direct contact with each other, but also includes configurations in which element y and element p are not in direct contact with each other. “Element y and element R are equal” means simply that element y and element p are substantially equal and includes manufacturing errors and the like. In addition, “element a and element p are laminated” means simply that element a and element p are lined up in the vertical direction and it does not matter whether element a and element p are in direct contact with each other.

### 1. First Embodiment

### 1-1. Overall Configuration of Image Forming Device 100

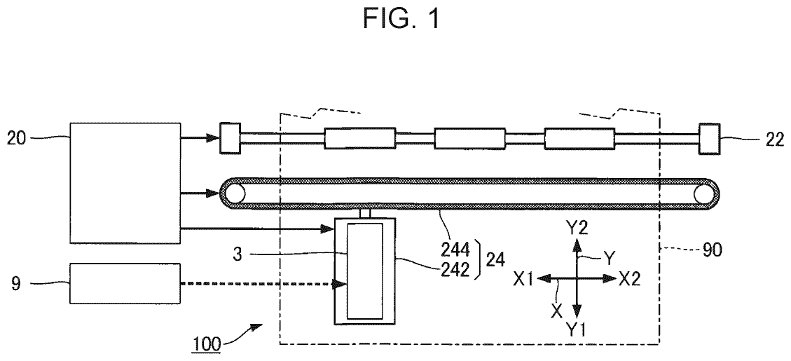

FIG. 1 is a schematic diagram illustrating the configuration of an image forming device 100 according to a first embodiment. Below, for convenience of description, a description will be given using, as appropriate, the X-axis, Y-axis, and Z-axis, which are mutually orthogonal. In addition, one direction along the X-axis is denoted as the X1 direction and the direction opposite to the X1 direction is denoted as the X2 direction. Similarly, one direction along the Y-axis is denoted as the Y1 direction and the direction opposite to the Y1 direction is denoted as the Y2 direction. One direction along the Z-axis is denoted as the Z1 direction and the direction opposite to the Z1 direction is denoted as the Z2 direction. The view in the direction along the Z-axis is called the “plan view”. In addition, the “laminating direction” is the direction along the Z-axis. The Z-axis is typically a vertical axis. The Z2 direction is the upper side and the Z1 direction is the lower side. However, the Z-axis does not have to be the vertical axis. In addition, the X-axis, Y-axis, and Z-axis are typically mutually orthogonal, but may intersect at, for example, angles within a range of 800 or more and 100° or less without being limited thereto.

The image forming device 100 in FIG. 1 is an ink jet printing device that ejects ink, which is an example of a liquid, onto a medium 90. The medium 90 is typically printing paper, but a printing target of any material such as a resin film or fabric may be used as the medium 90. As illustrated in FIG. 1, the image forming device 100 is provided with a liquid container 9 that stores ink. For example, a cartridge that is able to be attached to and detached from the image forming device 100, a bag-shaped ink pack formed of a flexible film, or an ink tank that is able to be refilled with ink is used as the liquid container 9.

The image forming device 100 is provided with a control unit 20, a medium transport mechanism 22, a movement mechanism 24, and a liquid ejection head 3. The control unit 20 includes one or a plurality of processing circuits, such as a Central Processing Unit (CPU) or a Field Programmable Gate Array (FPGA), and one or a plurality of storage circuits, such as a semiconductor memory, and controls each element of the image forming device 100 in an integrated manner.

The medium transport mechanism 22 transports the medium 90 in a direction along the Y-axis under the control of the control unit 20. In addition, the movement mechanism 24 reciprocates the liquid ejection head 3 along the X-axis under the control of the control unit 20. The movement mechanism 24 is provided with an approximately box-shaped transport body 242 that accommodates the liquid ejection head 3, and a transport belt 244 to which the transport body 242 is fixed. It is also possible to adopt a configuration in which a plurality of liquid ejection heads 3 are mounted on the transport body 242, or a configuration in which the liquid container 9 is mounted on the transport body 242 together with the liquid ejection head 3.

The liquid ejection head 3 ejects ink supplied from the liquid container 9 from a plurality of nozzles onto the medium 90 under the control of the control unit 20. In parallel with the transport of the medium 90 by the medium transport mechanism 22 and the repeated reciprocating of the transport body 242, each of the liquid ejection heads 3 ejects ink onto the medium 90, thereby forming an image on the surface of the medium 90.

The image forming device 100 is a serial head type in which the liquid ejection head 3 reciprocates over the medium 90. However, the image forming device 100 may be a line head type in which the liquid ejection head 3 is fixed.

### 1-2. Overall Configuration of Liquid Ejection Head 3

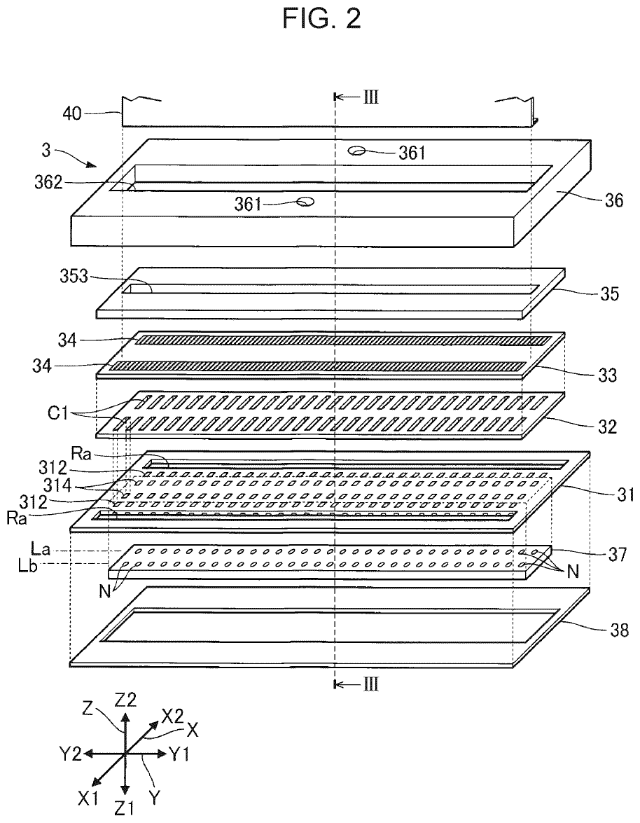

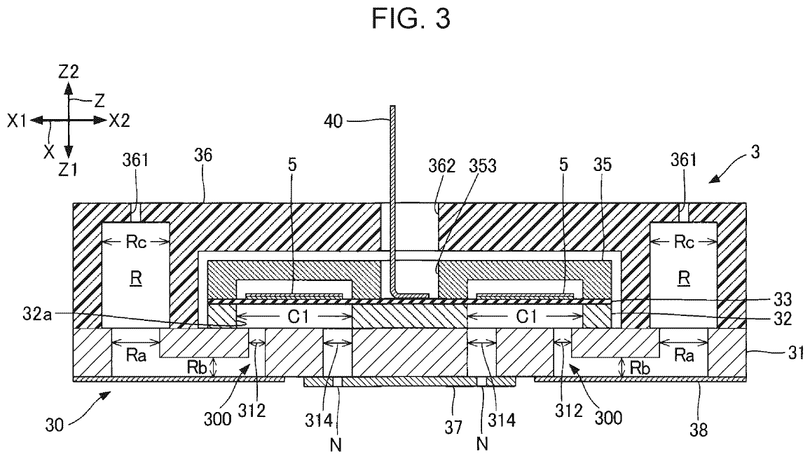

FIG. 2 is an exploded perspective diagram of the liquid ejection head 3 shown in FIG. 1. FIG. 3 is a cross-sectional diagram of a part of the liquid ejection head 3 shown in FIG. 1 taken along the line III-III in FIG. 2. The cross-section shown in FIG. 3 is parallel to the X-Z plane. The Z-axis is an axis along the direction of ink ejection by the liquid ejection head 3.

As illustrated in FIG. 2, the liquid ejection head 3 is provided with a plurality of nozzles N arrayed along the Y-axis. The plurality of nozzles N in the first embodiment are divided into a first row La and a second row Lb arranged side by side at intervals along the X-axis. Each of the first row La and the second row Lb is a collection of a plurality of nozzles N arrayed linearly along the Y-axis. The liquid ejection head 3 has a structure in which elements related to each nozzle N in the first row La and elements related to each nozzle N in the second row Lb are arranged in an approximately plane-symmetrical manner. In the following description, the elements corresponding to the first row La will be mainly described and the description of the elements corresponding to the second row Lb will not be repeated, as appropriate.

As illustrated in FIG. 2 and FIG. 3, the liquid ejection head 3 is provided with a flow path forming substrate 31, a pressure chamber substrate 32, a vibration plate 33, a nozzle plate 37, a vibration absorber 38, a plurality of piezoelectric elements 5, a sealing body 35, a housing portion 36, and a wiring substrate 40. Each of the flow path forming substrate 31, the pressure chamber substrate 32, the vibration plate 33, the nozzle plate 37, the vibration absorber 38, the sealing body 35, and the housing portion 36 is a long plate-like member along the Y-axis. In addition, the nozzle plate 37, the flow path forming substrate 31, the pressure chamber substrate 32, the vibration plate 33, and the sealing body 35 are lined up in this order in the Z2 direction.

The nozzle plate 37 is a plate-like member in which a plurality of nozzles N are formed. Each of the plurality of nozzles N is a circular through-hole that ejects ink. The nozzle plate 37 is bonded to the Z1-direction surface of the flow path forming substrate 31, for example, by an adhesive.

The flow path forming substrate 31 forms flow paths through which ink flows. Specifically, the flow path forming substrate 31 is formed with spaces Ra, relay liquid chambers Rb, a plurality of supply flow paths 312, and a plurality of communication flow paths 314. The spaces Ra are long openings formed along the Y-axis. Each of the supply flow paths 312 and the communication flow paths 314 is a through-hole formed for each nozzle N. Each of the communication flow paths 314 overlaps with a corresponding nozzle N in the plan view from the Z1 direction. The relay liquid chambers Rb are elongated spaces formed along the Y-axis across the plurality of nozzles N and cause the spaces Ra and the plurality of supply flow paths 312 to communicate with each other. The pressure chamber substrate 32 is bonded to the Z2 direction surface of the flow path forming substrate 31 using an adhesive.

The pressure chamber substrate 32 is formed with a plurality of pressure chambers C1. The ink ejected from the nozzles N is stored in the pressure chambers C1. The pressure chambers C1 are positioned between the nozzle plate 37 and the vibration plate 33 and are spaces formed by inner wall surfaces 32a of the pressure chamber substrate 32. The pressure chambers C1 are formed for each nozzle N. The pressure chambers C1 are elongated spaces provided to extend in the X1 direction. The plurality of pressure chambers C1 are lined up along the Y-axis. Each of the pressure chambers C1 communicates with the communication flow paths 314 and the supply flow paths 312. Accordingly, the pressure chambers C1 communicate with the nozzles N via the communication flow paths 314 and also communicate with the spaces Ra via the supply flow paths 312 and the relay liquid chambers Rb.

The nozzle plate 37, the flow path forming substrate 31, and the pressure chamber substrate 32 are manufactured by processing a single crystal substrate of silicon (Si) using semiconductor manufacturing techniques such as photolithography and etching, for example. However, any known material or manufacturing method may be adopted to manufacture the nozzle plate 37, the flow path forming substrate 31, and the pressure chamber substrate 32.

The vibration plate 33 is joined to the surface of the pressure chamber substrate 32 opposite to the flow path forming substrate 31. The vibration plate 33 is arranged over the pressure chambers C1 and is elastically deformable. The vibration plate 33 is a plate-like member formed in a long rectangular shape along the Y-axis in the plan view. The vibration plate 33 and the pressure chamber may be integrally configured or may be configured as separate bodies and bonded using an adhesive or the like.

The piezoelectric elements 5 are formed at the surface of the vibration plate 33 on the opposite side to the pressure chambers C1. The piezoelectric elements 5 are provided for each of the pressure chambers C1. The piezoelectric elements 5 are elongated along the X-axis in the plan view. The piezoelectric elements 5 are driving elements that are driven by the application of a driving signal and apply pressure to the ink in the pressure chambers C1.

The sealing body 35 is bonded to the vibration plate 33, for example, by an adhesive. The sealing body 35 is a structure that protects the plurality of piezoelectric elements 5 and reinforces the mechanical strength of the pressure chamber substrate 32 and the vibration plate 33. The sealing body 35 has recesses formed at the surface facing the vibration plate 33. The plurality of piezoelectric elements 5 are accommodated inside the recesses. In addition, the sealing body 35 also has a space 353 through which the wiring substrate 40 is inserted.

The housing portion 36 is bonded to the flow path forming substrate 31, for example, by an adhesive. The housing portion 36 is a case for storing ink to be supplied to the plurality of pressure chambers C1. The housing portion 36 is formed, for example, by injection molding a resin material. The housing portion 36 is formed with spaces Rc, supply ports 361, and a space 362. The supply ports 361 are conduits through which ink is supplied from the liquid container 9 and which communicate with the spaces Rc. The spaces Rc communicate with the spaces Ra of the flow path forming substrate 31. The spaces formed by the spaces Rc and the spaces Ra function as liquid storage chambers R that store ink to be supplied to the plurality of pressure chambers C1. The ink supplied from the liquid container 9 and passed through the supply ports 361 is stored in the liquid storage chambers R. The ink stored in the liquid storage chambers R branches from the relay liquid chambers Rb to each supply flow path 312 and is supplied in parallel to the plurality of pressure chambers C1. In addition, the space 362 also overlaps with the space 353 of the sealing body 35 in the plan view. The wiring substrate 40 is inserted into the space 353 and the space 362.

The wiring substrate 40 is joined to the vibration plate 33. The wiring substrate 40 is a mounting component on which a plurality of wirings are formed for electrically joining the control unit 20 and the liquid ejection head 3. For example, a flexible substrate such as a flexible printed circuit (FPC) or a flexible flat cable (FFC) is suitably adopted for the wiring substrate 40. A driving signal and a reference voltage for driving the piezoelectric elements 5 are supplied to each of the piezoelectric elements 5 from the wiring substrate 40.

In addition, the vibration absorber 38 is bonded, for example, by an adhesive, to the surface of the flow path forming substrate 31 in the Z1 direction. The vibration absorber 38 is a flexible film that forms the wall surface of the spaces Ra and absorbs pressure fluctuations of the ink in the liquid storage chambers R.

In this liquid ejection head 3, when the piezoelectric elements 5 are flexed and deformed by applying a voltage, the vibration plate 33 is flexed and deformed, that is, vibrated, in a direction that reduces the volume of the pressure chambers C1. As a result, the pressure in the pressure chambers C1 changes, and the ink in the pressure chambers C1 is ejected from the nozzle N. The piezoelectric elements 5 return to the original position after the ink is ejected.

In addition, the liquid ejection head 3 is provided with all of each of the elements shown in FIG. 3, but the components of the liquid ejection head 3 do not need to include all of each of the elements, and additional elements may be provided.

### 1-3. Piezoelectric Element 5

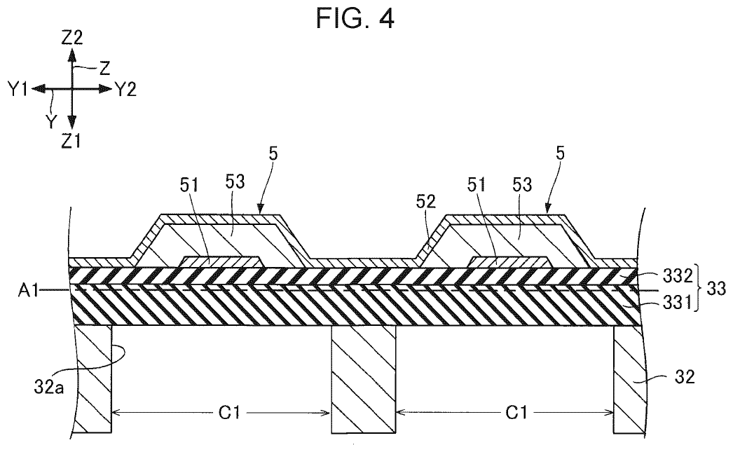

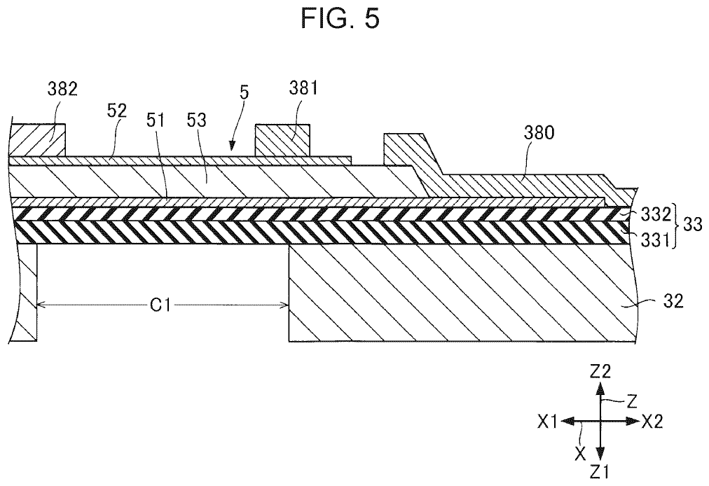

Each of FIG. 4 and FIG. 5 is a cross-sectional diagram showing the piezoelectric element 5 of FIG. 3. The cross-section shown in FIG. 4 is a cross-section parallel to the Y-Z plane. The cross-section shown in FIG. 5 is a cross-section parallel to the X-Z plane.

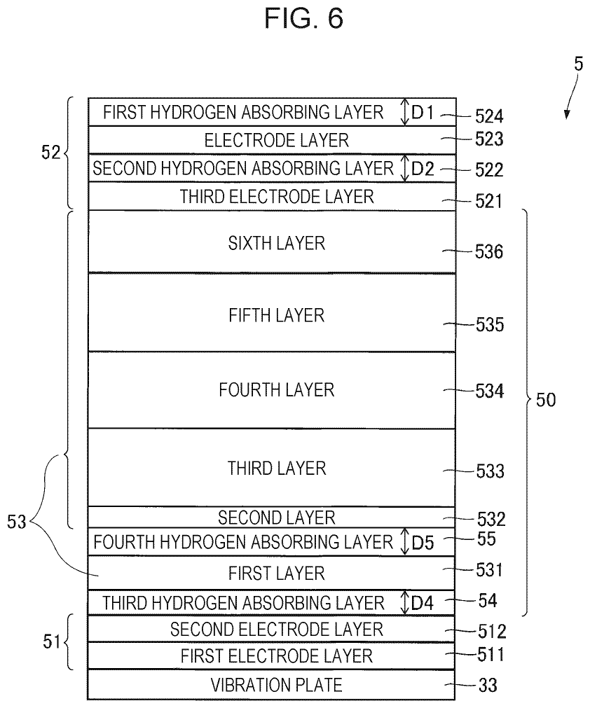

As shown in FIG. 4 and FIG. 5, the piezoelectric element 5 mainly has a lower electrode 51, a piezoelectric layer 53, and an upper electrode 52. The lower electrode 51, the piezoelectric layer 53, and the upper electrode 52 are laminated in the direction along the Z-axis, which is the laminating direction. In addition, as will be described below, the upper electrode 52 has a first hydrogen absorbing layer 524 and a second hydrogen absorbing layer 522, as shown in FIG. 6. In addition, as shown in FIG. 6, the piezoelectric element 5 further has a third hydrogen absorbing layer 54 and a fourth hydrogen absorbing layer 55. The piezoelectric layer 53, the third hydrogen absorbing layer 54, and the fourth hydrogen absorbing layer 55 may be collectively referred to as an intermediate layer 50 positioned between the lower electrode 51 and the upper electrode 52.

As shown in FIG. 4 and FIG. 5, the lower electrode 51 is provided above the vibration plate 33. The lower electrode 51 is an individual electrode provided for each piezoelectric element 5. A driving signal with a fluctuating voltage is applied to the lower electrode 51. The lower electrode 51 is elongated along the X-axis. The plurality of lower electrodes 51 are arrayed along the Y-axis at intervals. The lower electrodes 51 include a conductive material.

The piezoelectric layer 53 is provided above the lower electrode 51. The piezoelectric layer 53 is, for example, a strip-shaped dielectric film that is continuous along the Y-axis across the plurality of piezoelectric elements 5. The piezoelectric layer 53 has, for example, a strip-shape extending along the Y-axis and is separated for each piezoelectric element 5 by forming a plurality of notches. The piezoelectric layer 53 is formed of a perovskite-type complex oxide.

The upper electrode 52 is provided above the piezoelectric layer 53. The upper electrode 52 is a strip-shaped common electrode that extends along the Y-axis so as to be continuous across the plurality of the piezoelectric elements 5. A predetermined reference voltage is applied to the upper electrode 52. The upper electrode 52 includes a conductive material.

A voltage corresponding to the difference between the reference voltage applied to the upper electrode 52 and the driving voltage corresponding to the ejection amount supplied to the lower electrode 51 is applied to the piezoelectric layer 53. By applying a voltage between the lower electrode 51 and the upper electrode 52, the piezoelectric layer 53 deforms such that the piezoelectric element 5 flexes and deforms, that is, vibrates.

The vibration plate 33 is vibrated by the driving of the piezoelectric elements 5. In the illustrated example, the vibration plate 33 is formed of a laminate including a first vibration layer 331 and a second vibration layer 332. The first vibration layer 331 contacts the pressure chamber substrate 32. The second vibration layer 332 is arranged above the first vibration layer 331. The first vibration layer 331 is formed of an elastic material such as silicon oxide (SiOₓ). The second vibration layer 332 is formed of an insulating material such as zirconium oxide (ZrOₓ). The first vibration layer 331 is formed, for example, by thermally oxidizing a part of the pressure chamber substrate 32. The second vibration layer 332 is formed, for example, by a known film forming technique such as sputtering. The vibration plate 33 may be formed of one layer or formed of three or more layers.

FIG. 4 shows a neutral axis A1 of the vibration plate 33. The neutral axis A1 is the position where the compressive force and the contractive force are balanced and is the position in the vibration plate 33 where the stress in the axial direction along the X-Y plane is 0 (zero).

As shown in FIG. 5, two conductors 381 and 382 are arranged on the upper electrode 52. Each of the conductors 381 and 382 is a strip-shaped conductive film arranged along the edge of the upper electrode 52 in the X1 direction or the X2 direction and extending in the direction along the Y-axis. The conductors 381 and 382 are formed of an electrically conductive material with low resistance, such as gold. The conductors 381 and 382 suppress the voltage drops in the reference voltage in the upper electrode 52. In addition, the conductors 381 and 382 also function as weights that regulate the vibration region of the vibration plate 33. The conductors 381 and 382 may be omitted.

In addition, a joining wiring 380 is joined to one end of the lower electrode 51 in the longitudinal direction along the X-axis. The lower electrode 51 is electrically joined to the wiring substrate 40 via the joining wiring 380. The upper electrode 52 is electrically joined to the wiring substrate 40 via wiring or the like which is not shown.

In addition, in the present embodiment, the lower electrode 51 is an individual electrode and the upper electrode 52 is a common electrode, but the lower electrode 51 may be a common electrode and the upper electrode 52 may be an individual electrode.

FIG. 6 is a diagram schematically showing the piezoelectric element 5 shown in FIG. 4. As described above, the piezoelectric element 5 has the lower electrode 51, the piezoelectric layer 53, the upper electrode 52, the third hydrogen absorbing layer 54, and the fourth hydrogen absorbing layer 55. Each of the lower electrode 51, the piezoelectric layer 53, and the upper electrode 52 is formed of a plurality of layers. In addition, in the present embodiment, the third hydrogen absorbing layer 54 is arranged between the lower electrode 51 and the piezoelectric layer 53. The fourth hydrogen absorbing layer 55 is arranged between the plurality of layers that form the piezoelectric layer 53. Accordingly, the fourth hydrogen absorbing layer 55 is arranged inside the piezoelectric layer 53.

The lower electrode 51 has a first electrode layer 511 and a second electrode layer 512. The first electrode layer 511 is arranged above the vibration plate 33 and contacts the vibration plate 33. The first electrode layer 511 includes, for example, platinum (Pt). The thickness of the first electrode layer 511 along the Z-axis is not particularly limited, but is, for example, 50 nm or more and 120 nm or less.

The second electrode layer 512 is arranged between the first electrode layer 511 and the third hydrogen absorbing layer 54 and is in contact therewith. The second electrode layer 512 contains, for example, iridium (Ir). The thickness of the second electrode layer 512 along the Z-axis is not particularly limited, but is, for example, 5 nm or more and 50 nm or less. In addition, in the present embodiment, the thickness of the second electrode layer 512 is thinner than the thickness of the first electrode layer 511, but may be equal to or greater than the thickness of the first electrode layer 511.

In addition, in the present embodiment, the lower electrode 51 is formed of two layers, but may be formed of one layer or three or more layers. In addition, the first electrode layer 511 and the second electrode layer 512 may also be formed of a material other than the above-described materials as long as the material is a conductive material.

The third hydrogen absorbing layer 54 has a function of absorbing hydrogen present in each layer forming the piezoelectric elements 5 or between these layers. In particular, the third hydrogen absorbing layer 54 suitably absorbs hydrogen in the piezoelectric layer 53, hydrogen in the lower electrode 51, and hydrogen present at the interface of each layer below the piezoelectric layer 53.

In FIG. 6, the interface between the third hydrogen absorbing layer 54 and the piezoelectric layer 53 is illustrated as being clear, but does not have to be clear. For example, a part of the third hydrogen absorbing layer 54 may be embedded in the piezoelectric layer 53, may be dispersed therein, or may be integrated therewith. In addition, the intralayer composition of the third hydrogen absorbing layer 54 may be constant or may be a gradient. Accordingly, the composition of the third hydrogen absorbing layer 54 may differ between the piezoelectric layer 53 side and the lower electrode 51 side. In addition, the thickness of the third hydrogen absorbing layer 54 along the Z-axis is not particularly limited, but is, for example, 2 nm or more and 20 nm or less. In addition, the third hydrogen absorbing layer 54 may be formed of a plurality of layers.

The piezoelectric layer 53 is a laminate in which a first layer 531, a second layer 532, a third layer 533, a fourth layer 534, a fifth layer 535, and a sixth layer 536 are laminated in this order. The number of layers in the piezoelectric layer 53 is not limited to six and may be five or less or seven or more. However, forming the piezoelectric layer 53 from a plurality of layers rather than a single layer makes it possible to form the piezoelectric layer 53 having excellent piezoelectric properties.

Each layer forming the piezoelectric layer 53 is formed of a perovskite-type complex oxide. More specifically, each layer includes, for example, lead titanate (PbTiO₃), lead zirconate titanate (PZT: Pb(Zr,Ti)O₃), lead zirconate (PbZrO₃), lead lanthanum titanate ((Pb,La),TiO₃), lead lanthanum zirconate titanate ((Pb,La)(Zr,Ti)O₃), lead zirconium niobate titanate (Pb(Zr,Ti,Nb)O₃), lead magnesium zirconium niobate titanate (Pb(Zr,Ti)(Mg,Nb)O₃), and the like.

Each layer forming the piezoelectric layer 53 may be formed of a non-lead material. Examples of non-lead-based materials include bismuth ferrate (BiFeO3), barium titanate (BaTiO3), potassium sodium niobate ((K,Na)(NbO3), and the like.

In addition, the thickness of each layer of the piezoelectric layer 53 is not particularly limited, but is, for example, 90 nm or more and 250 nm or less.

The first layer 531 is arranged between the third hydrogen absorbing layer 54 and the fourth hydrogen absorbing layer 55 and is in contact therewith. The fourth hydrogen absorbing layer 55 is arranged between the first layer 531 and the second layer 532 and is in contact therewith.

The fourth hydrogen absorbing layer 55 has the function of absorbing hydrogen present in each layer forming the piezoelectric elements 5 or between these layers. In particular, the fourth hydrogen absorbing layer 55 suitably absorbs hydrogen in the first layer 531 and the second layer 532.

In FIG. 6, each of the interface between the fourth hydrogen absorbing layer 55 and the second layer 532 and the interface between the fourth hydrogen absorbing layer 55 and the first layer 531 is illustrated as being clear, but does not have to be clear. For example, a part of the fourth hydrogen absorbing layer 55 may be embedded in the first layer 531 or the second layer 532, may be dispersed therein, or may be integrated therewith. In addition, the intralayer composition of the fourth hydrogen absorbing layer 55 may be constant or may be a gradient. Accordingly, the composition of the fourth hydrogen absorbing layer 55 may be different between the second layer 532 side and the first layer 531 side. In addition, the thickness of the fourth hydrogen absorbing layer 55 along the Z-axis is not particularly limited, but is, for example, 2 nm or more and 20 nm or less. In addition, in the present embodiment, the film thickness D5 of the fourth hydrogen absorbing layer 55 is thinner than the film thickness D4 of the third hydrogen absorbing layer 54, but may be equal to or greater than the film thickness D4 of the third hydrogen absorbing layer 54. In addition, the fourth hydrogen absorbing layer 55 may be formed of a plurality of layers.

The upper electrode 52 is a structure in which a third electrode layer 521, the second hydrogen absorbing layer 522, an electrode layer 523, and the first hydrogen absorbing layer 524 are laminated in this order. The third electrode layer 521 is arranged above the piezoelectric layer 53 and contacts the sixth layer 536 of the piezoelectric layer 53. The third electrode layer 521 includes, for example, iridium oxide (IrOₓ). The thickness of the third electrode layer 521 along the Z-axis is not particularly limited, but is, for example, 5 nm or more and 20 nm or less.

The second hydrogen absorbing layer 522 includes, for example, titanium oxide (TiOₓ). The film thickness D2 of the second hydrogen absorbing layer 522 along the Z-axis is not particularly limited, but is, for example, 2 nm or more and 20 nm or less. The second hydrogen absorbing layer 522 has the function of absorbing hydrogen present in the upper electrode 52, hydrogen present in the piezoelectric element 5, and hydrogen penetrating from the outside of the piezoelectric element 5. The second hydrogen absorbing layer 522 may have a constant composition within the layer or may be a gradient. In addition, the second hydrogen absorbing layer 522 may also be formed of a plurality of layers.

The electrode layer 523 includes, for example, iridium (Ir). The thickness of the electrode layer 523 along the Z-axis is not particularly limited, but is, for example, 5 nm or more and 50 nm or less.

The first hydrogen absorbing layer 524 includes, for example, titanium (Ti). The film thickness D1 of the first hydrogen absorbing layer 524 along the Z-axis is not particularly limited, but is, for example, 5 nm or more and 30 nm or less. The first hydrogen absorbing layer 524 has the function of absorbing hydrogen present in the upper electrode 52, hydrogen present in the piezoelectric element 5, and hydrogen penetrating from the outside of the piezoelectric element 5. The first hydrogen absorbing layer 524 may have a constant composition within the layer or may be a gradient. In addition, the first hydrogen absorbing layer 524 may be formed of a plurality of layers.

In the example of FIG. 6, an orientation control layer for controlling the orientation of the piezoelectric layer 53 is not provided between the third hydrogen absorbing layer 54 and the piezoelectric layer 53, but such an arrangement control layer may be provided. In addition, the third hydrogen absorbing layer 54 may have the function of the orientation control layer. As a result of the third hydrogen absorbing layer 54 having the function of the orientation control layer, there is no need to provide a separate orientation control layer, thus, manufacturing is easy. The orientation control layer, for example, preferentially orients the crystals in the higher layers in a predetermined plane orientation or adjusts the degree of orientation in a predetermined plane orientation.

Similarly, an orientation control layer for controlling the orientation of the second layer 532 is not provided between the fourth hydrogen absorbing layer 55 and the second layer 532, but such an arrangement control layer may be provided. The fourth hydrogen absorbing layer 55 may have the function of the orientation control layer. If so, as a result of the fourth hydrogen absorbing layer 55 having the function of the orientation control layer, there is no need to provide a separate orientation control layer, thus, manufacturing is easy.

### 1-4. Hydrogen Absorbing Layer

As described above, the upper electrode 52 has the first hydrogen absorbing layer 524. The piezoelectric element 5 having the first hydrogen absorbing layer 524 makes it possible to absorb hydrogen outside the piezoelectric element 5, hydrogen present at the interface between the upper electrode 52 and other layers, hydrogen present in the piezoelectric layer 53, or hydrogen for which there is a concern of entry into the piezoelectric layer 53.

The hysteresis characteristics of the piezoelectric element 5 change significantly in comparison with the design stage depending on the hydrogen content of the piezoelectric layer 53. When the hysteresis characteristics change significantly, there is a concern that the difference in the amount of displacement may become large among the plurality of piezoelectric elements 5. For this reason, in order to reduce the difference in the amount of displacement among the plurality of piezoelectric elements 5, it is necessary to change the driving voltage and waveform for each piezoelectric element 5. Adjusting the differences in the amounts of displacement among the plurality of piezoelectric elements 5 in this manner is time-consuming and the usability is poor.

In addition, when the piezoelectric element 5 has the piezoelectric layer 53 formed from a plurality of layers, the hydrogen content of the piezoelectric layer 53 tends to be high compared to the design stage. As will be described below, the piezoelectric layer 53 is formed by repeatedly film-forming and firing each of the plurality of layers a plurality of times. It is considered that hydrogen enters the piezoelectric layer 53 during this manufacturing process. In addition, differences in the amounts of displacement occur among the plurality of piezoelectric elements 5 depending on the hydrogen content of the piezoelectric layer 53 not only when the composition in the piezoelectric layer 53 is constant, but also when there is a composition gradient in the piezoelectric layer 53.

As described above, in the piezoelectric element 5 of the present embodiment, the upper electrode 52 has the first hydrogen absorbing layer 524. For this reason, during the manufacture and use of the piezoelectric element 5, it is possible to absorb hydrogen present in the piezoelectric layer 53 or hydrogen for which there is a concern of entry into the piezoelectric layer 53. For this reason, it is possible to suppress the hysteresis characteristics of the piezoelectric element 5 from changing significantly in comparison with the design stage depending on the hydrogen content of the piezoelectric layer 53. As a result, it is possible to suppress increases in the difference in the amount of displacement due to changes in the hysteresis characteristics of the plurality of piezoelectric elements 5. Thus, it is not necessary to change the driving voltage and waveform for each piezoelectric element 5 and it is possible to suppress deterioration in usability. For this reason, the liquid ejection head 3 provided with the above-described piezoelectric elements 5 has excellent displacement characteristics and usability.

In addition, in the present embodiment, as shown in FIG. 4, the upper electrode 52 is a common electrode positioned above the piezoelectric layer 53 and provided to cover the piezoelectric layer 53. For this reason, compared to the case where the upper electrode 52 is an individual electrode that does not cover the piezoelectric layer 53, it is possible to suppress hydrogen from entering into the piezoelectric layer 53 from outside the piezoelectric element 5. In particular, even after manufacturing, it is possible to effectively suppress hydrogen from entering into the piezoelectric layer 53 from outside the piezoelectric element 5.

The first hydrogen absorbing layer 524 is formed of a material capable of absorbing hydrogen. Specifically, the first hydrogen absorbing layer 524 includes a hydrogen storage material able to compound with hydrogen to become a hydride. The hydrogen storage material absorbs or releases hydrogen depending on temperature or pressure. When the first hydrogen absorbing layer 524 absorbs hydrogen, hydrogen penetrates into the gaps in the crystal lattice of the hydrogen storage material. The hydrogen storage material includes a metal such as magnesium (Mg), vanadium (V), lanthanum (La), and titanium (Ti), or an alloy or compound including the metal. The first hydrogen absorbing layer 524 is formed of, for example, titanium or lead titanate (PbTiO₃). In addition, the first hydrogen absorbing layer 524 is formed of, for example, a complex oxide including bismuth (Bi), iron (Fe), titanium (Ti), and lead (Pb).

In addition, the second hydrogen absorbing layer 522, the third hydrogen absorbing layer 54, and the fourth hydrogen absorbing layer 55 each similarly includes a hydrogen storage material able to compound with hydrogen to become a hydride.

In addition, the film thickness D1 of the first hydrogen absorbing layer 524 is not particularly limited, but is preferably 10 nm or more and 25 nm or less. The film thickness D1 of the first hydrogen absorbing layer 524 being within the above range makes it possible to suppress the diffusion of hydrogen from the first hydrogen absorbing layer 524 due to aging degradation while absorbing hydrogen, in comparison with when the film thickness is outside this range. Thus, it is possible to provide a piezoelectric element having excellent displacement characteristics in a stable manner.

In addition, as described above, the upper electrode 52 has the second hydrogen absorbing layer 522 that is different from the first hydrogen absorbing layer 524. Having the second hydrogen absorbing layer 522 in addition to the first hydrogen absorbing layer 524 makes it possible to more effectively suppress hydrogen from entering into the piezoelectric layer 53.

In the present embodiment, the second hydrogen absorbing layer 522 is positioned at a lower layer than the first hydrogen absorbing layer 524. Accordingly, the second hydrogen absorbing layer 522 is arranged closer to the piezoelectric layer 53 than the first hydrogen absorbing layer 524. Providing the second hydrogen absorbing layer 522 close to the piezoelectric layer 53 makes it possible to suitably absorb hydrogen at the interface between the piezoelectric layer 53 and the upper electrode 52.

The second hydrogen absorbing layer 522 may be provided above the first hydrogen absorbing layer 524. In addition, in the present embodiment, the second hydrogen absorbing layer 522 is spaced apart from the first hydrogen absorbing layer 524, but may be in contact with the first hydrogen absorbing layer 524. In addition, the first hydrogen absorbing layer 524 and the second hydrogen absorbing layer 522 may be formed of the same material or different materials.

In addition, in the direction along the Z-axis, which is the laminating direction, the film thickness D1 of the first hydrogen absorbing layer 524 is preferably thicker than the film thickness D2 of the second hydrogen absorbing layer 522. In the present embodiment, the first hydrogen absorbing layer 524 is closer to the outside than the second hydrogen absorbing layer 522. Making the film thickness D1 of the first hydrogen absorbing layer 524 thicker makes it possible to more effectively suppress hydrogen from entering into the piezoelectric layer 53. In addition, making the film thickness D2 of the second hydrogen absorbing layer 522 thin makes it possible to reduce the amount of hydrogen absorbed by the second hydrogen absorbing layer 522. Even when hydrogen is released from the second hydrogen absorbing layer 522 due to changes over time or the like, it is possible to reduce the amount of hydrogen that enters the piezoelectric layer 53.

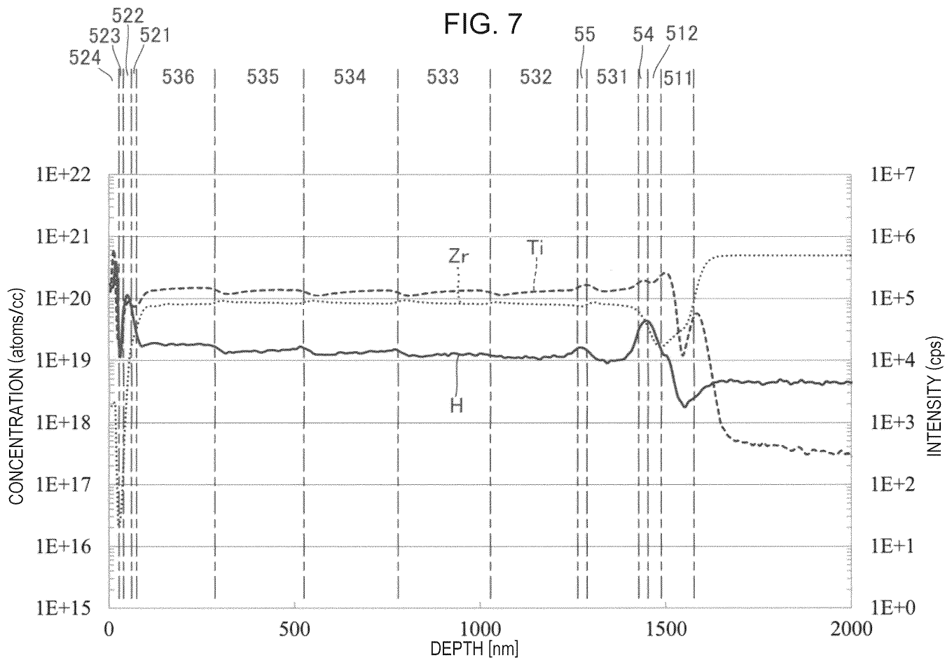

The film thickness D1 may be equal to or less than the film thickness D2. FIG. 7 is a diagram showing the measurement results of the piezoelectric element 5 of the present embodiment using a secondary ion mass spectrometer (SIMS). In FIG. 7, the material of the first electrode layer 511 is platinum and the material of the second electrode layer 512 is iridium. The third hydrogen absorbing layer 54 includes titanium. The material of each layer of the piezoelectric layer 53 is lead zirconate titanate (PZT). The fourth hydrogen absorbing layer 55 includes titanium. The material of the third electrode layer 521 is iridium oxide and the material of the electrode layer 523 is iridium. The material of the second hydrogen absorbing layer 522 is titanium oxide and the material of the first hydrogen absorbing layer 524 is titanium.

The horizontal axis in FIG. 7 is the depth [nm]. Since the analysis was performed in the Z1 direction from the upper electrode 52, the shallower side is the upper electrode 52 side and the deeper side is the lower electrode 51 side.

The vertical axis of FIG. 7 shows the hydrogen concentration [atoms/cc]. The hydrogen concentration is the result of quantitative analysis using a standard sample doped with a known concentration of the target element. Titanium and zirconium are shown in terms of ion intensity. In addition, in FIG. 7, clear lines are drawn along the interfaces between each layer, but the positions of the interfaces may shift slightly depending on the determined contents.

As is clear from FIG. 7, the hydrogen content of the first hydrogen absorbing layer 524 is greater than the hydrogen content included in the second hydrogen absorbing layer 522. Therefore, it is considered that the first hydrogen absorbing layer 524 makes it possible to more effectively suppress hydrogen from entering into the piezoelectric layer 53 from the outside of the piezoelectric element 5. In addition, the hydrogen content of the second hydrogen absorbing layer 522 being small makes it possible to suppress hydrogen from entering into the piezoelectric layer 53 even when hydrogen is released from the second hydrogen absorbing layer 522 due to changes over time or the like.

The hydrogen content of the first hydrogen absorbing layer 524 may be equal to or less than the hydrogen content of the second hydrogen absorbing layer 522.

In addition, as described above, the upper electrode 52 has the electrode layer 523 formed of a conductive material. In the present embodiment, the electrode layer 523 is provided between the second hydrogen absorbing layer 522 and the first hydrogen absorbing layer 524 in the direction along the Z-axis, which is the laminating direction. Accordingly, the electrode layer 523 is interposed between the second hydrogen absorbing layer 522 and the first hydrogen absorbing layer 524.

When the electrode layer 523 is film-formed by sputtering, for example, there may be a large amount of hydrogen on the surface of the electrode layer 523. In this case, the second hydrogen absorbing layer 522 and the first hydrogen absorbing layer 524 are provided to interpose the electrode layer 523 therebetween, such that it is possible to suitably absorb the hydrogen on the surface of the electrode layer 523 using the second hydrogen absorbing layer 522 and the first hydrogen absorbing layer 524. For this reason, it is possible to effectively suppress hydrogen from entering into the piezoelectric layer 53.

The electrode layer 523 may be provided at a location other than between the second hydrogen absorbing layer 522 and the first hydrogen absorbing layer 524.

In addition, as is clear from FIG. 7, the hydrogen content of the electrode layer 523 is smaller than the hydrogen content of the first hydrogen absorbing layer 524. Furthermore, the hydrogen content of the electrode layer 523 is also smaller than the hydrogen content of the second hydrogen absorbing layer 522. Providing the first hydrogen absorbing layer 524 and the second hydrogen absorbing layer 522 makes it possible to reduce the hydrogen content in the electrode layer 523. For this reason, it is possible to suppress concerns that the electrical resistance may increase due to deficiency or deterioration of the crystallinity in the electrode layer 523. In addition, the low hydrogen content of the electrode layer 523 makes it possible to suppress an increase in electrical resistance.

In addition, the other third electrode layer 521 different from the electrode layer 523 is provided between the second hydrogen absorbing layer 522 and the piezoelectric layer 53. As is clear from FIG. 7, the hydrogen content of the third electrode layer 521 is smaller than each of the hydrogen content of the first hydrogen absorbing layer 524 and the hydrogen content of the second hydrogen absorbing layer 522. For this reason, it is possible to suppress concerns that the electrical resistance may increase due to deficiency or deterioration of the crystallinity in the third electrode layer 521. In addition, the low hydrogen content of the third electrode layer 521 makes it possible to suppress an increase in electrical resistance. In addition, the low hydrogen content of the third electrode layer 521 makes it possible to reduce the hydrogen entering into the piezoelectric layer 53 from the upper electrode 52.

As described above, the piezoelectric element 5 has the third hydrogen absorbing layer 54. In the present embodiment, the third hydrogen absorbing layer 54 is arranged between the piezoelectric layer 53 and the lower electrode 51. The third hydrogen absorbing layer 54 has a function of absorbing hydrogen. Providing the third hydrogen absorbing layer 54 on the lower electrode 51 side of the piezoelectric layer 53 makes it possible to suppress hydrogen from entering into the piezoelectric layer 53 from the lower electrode 51 side, compared to when the third hydrogen absorbing layer 54 is not provided.

The third hydrogen absorbing layer 54 may be omitted.

Furthermore, the piezoelectric element 5 has the fourth hydrogen absorbing layer 55. In the present embodiment, the fourth hydrogen absorbing layer 55 is positioned in the piezoelectric layer 53. Specifically, the fourth hydrogen absorbing layer 55 is provided between the first layer 531 and the second layer 532. Providing the fourth hydrogen absorbing layer 55 makes it possible to reduce the hydrogen content of the piezoelectric layer 53, compared to when the fourth hydrogen absorbing layer 55 is not provided.

The fourth hydrogen absorbing layer 55 may be omitted.

As is clear from FIG. 7, the hydrogen content of the first layer 531 is smaller than the hydrogen content of the second layer 532. The first layer 531 is laminated above the third hydrogen absorbing layer 54 and is in direct contact with the third hydrogen absorbing layer 54. The second layer 532 is laminated above the first layer 531. Furthermore, the first layer 531 is arranged between the third hydrogen absorbing layer 54 and the fourth hydrogen absorbing layer 55 and is in contact therewith. For this reason, the functions of the third hydrogen absorbing layer 54 and the fourth hydrogen absorbing layer 55 make it possible to reduce the hydrogen content of the first layer 531 to be lower than the hydrogen content of the second layer 532. The hydrogen content of the first layer 531 may be equal to or greater than the hydrogen content of the second layer 532.

In addition, as is clear from FIG. 7, the hydrogen content of the third hydrogen absorbing layer 54 is greater than the hydrogen content of the first layer 531. The third hydrogen absorbing layer 54 absorbing hydrogen makes it possible to reduce the hydrogen content of the first layer 531. Providing the third hydrogen absorbing layer 54 makes it possible to suppress hydrogen from entering into the piezoelectric layer 53 including the first layer 531 after manufacturing the piezoelectric element 5 and during use. In addition, the third hydrogen absorbing layer 54 also suppresses the increase in the hydrogen content of the first layer 531 during manufacture, thereby making it possible to suppress increases in the hydrogen content of each of the second layer 532 to the sixth layer 536 on the first layer 531.

In addition, as shown in FIG. 6, the third hydrogen absorbing layer 54 is provided on the lower electrode 51. Furthermore, the third hydrogen absorbing layer 54 may be provided not only above the lower electrode 51, but also on the portion of the vibration plate 33 shown in FIG. 4 above which the lower electrode 51 is not provided, that is, on the vibration plate 33. By providing the third hydrogen absorbing layer 54 in this manner, the entire lower surface of the first layer 531 is in contact with the third hydrogen absorbing layer 54. For this reason, compared to a form in which only a part of the lower surface of the first layer 531 is in contact with the third hydrogen absorbing layer 54, the function of the third hydrogen absorbing layer 54 makes it possible to suppress an increase in the hydrogen content of the first layer 531. The hydrogen content of the third hydrogen absorbing layer 54 may be equal to or less than the hydrogen content of the first layer 531.

In addition, the hydrogen content of the second layer 532 of the piezoelectric layer 53 is smaller than the hydrogen content of the third layer 533. The second layer 532 is laminated above the fourth hydrogen absorbing layer 55 and is in contact with the fourth hydrogen absorbing layer 55. The third layer 533 is laminated above the second layer 532. For this reason, the second layer 532 is arranged closer to the fourth hydrogen absorbing layer 55 than the third layer 533. Therefore, the hydrogen absorbing function of the fourth hydrogen absorbing layer 55 makes it possible to make the hydrogen content of the second layer 532 small.

In addition, as is clear from FIG. 7, the hydrogen content of the fourth hydrogen absorbing layer 55 is smaller than the hydrogen content of the third hydrogen absorbing layer 54. It is considered that the third hydrogen absorbing layer 54 and the fourth hydrogen absorbing layer 55 mainly suppress hydrogen from entering into the piezoelectric layer 53 from the lower electrode 51 side. It is considered that even the third hydrogen absorbing layer 54 alone is able to sufficiently absorb hydrogen from the lower electrode 51 side. For this reason, it is considered that the hydrogen content of the fourth hydrogen absorbing layer 55 is smaller than the hydrogen content of the third hydrogen absorbing layer 54. The hydrogen content of the fourth hydrogen absorbing layer 55 may be equal to or greater than the hydrogen content of the third hydrogen absorbing layer 54.

In the present embodiment, in the direction along the Z-axis, the film thickness D5 of the fourth hydrogen absorbing layer 55 is thinner than the film thickness D4 of the third hydrogen absorbing layer 54. Accordingly, the film thickness D4 is thicker than the film thickness D5. Making the film thickness D4 thicker than the film thickness D5 makes it possible to suppress hydrogen from entering into the piezoelectric layer 53 from the lower electrode 51 side using the third hydrogen absorbing layer 54, compared to when the film thickness D4 is thinner. The film thickness D5 of the fourth hydrogen absorbing layer 55 may be equal to or greater than the film thickness D4 of the third hydrogen absorbing layer 54.

As shown in FIG. 7, the variation in the hydrogen content at a central section of the piezoelectric element 5 in the laminating direction is preferably 24% or less with respect to the average value. The central section is a layer positioned in the center of the piezoelectric layer 53 in the laminating direction and is not in contact with any layer other than the piezoelectric layer 53. In the example of FIG. 6, the central section is the third layer 533 and the fourth layer 534. These layers are not in contact with the fourth hydrogen absorbing layer 55 and the upper electrode 52, which are layers other than the piezoelectric layer 53.

In the example of FIG. 7, the variation is 24% or less. Making the variation 24% or less makes it possible to suppress the slope of the hysteresis curve showing the relationship between the voltage and polarization of the piezoelectric layer 53 from becoming steeper, compared to when the variation exceeds 24%. In addition, it is possible to suppress the shape of the hysteresis curve from changing over time from the time of design. Thus, it is possible to suppress the deterioration of the displacement characteristics of the piezoelectric element 5. The variation in the hydrogen content in the central section may exceed 24% with respect to the average value.

In addition, as shown in FIG. 7, each of the hydrogen contents of the third layer 533 and the fourth layer 534 in the central section of the piezoelectric layer 53 is suppressed in the same manner as the hydrogen content of the first layer 531. Specifically, for example, the average hydrogen content of each layer in the central section of the piezoelectric layer 53 is preferably less than 1E+20 [atoms/cc] and is more preferably less than 1E+19 [atoms/cc]. “E” represents a power of 10. For example, 1E+20 represents 1×10²⁰, and 1E+19 represents 1×10¹⁹. Regarding the piezoelectric element 5, the performance of the piezoelectric element 5 increases as the displacement of the layer away from the neutral axis A1 of the piezoelectric layer 53 shown in FIG. 4 increases. The third layer 533 and the fourth layer 534 are farther from the neutral axis A1 than the first layer 531. Reducing the hydrogen content of each of the third layer 533 and the fourth layer 534, which are farther from the neutral axis A1, makes it possible to suppress the deterioration of the displacement characteristics of the piezoelectric element 5.

In addition, as described above, the piezoelectric layer 53 is formed of a perovskite-type complex oxide and is preferably formed of lead zirconate titanate (PZT) in particular. Due to the piezoelectric layer being PZT, the effect of suppressing changes in the hysteresis characteristics of the piezoelectric element 5 due to the provision of the third hydrogen absorbing layer 54 is particularly remarkable. Furthermore, when the piezoelectric layer 53 is formed of a plurality of layers, it is possible for the effect of providing the third hydrogen absorbing layer 54 to be particularly remarkable.

In addition, each of the first hydrogen absorbing layer 524, the second hydrogen absorbing layer 522, the third hydrogen absorbing layer 54, and the fourth hydrogen absorbing layer 55 particularly preferably includes titanium. Furthermore, each of these layers is preferably formed of titanium. Titanium has an excellent hydrogen absorbing performance. For this reason, including titanium in these layers makes it possible to absorb more hydrogen for which there is a concern of entry into the piezoelectric layer 53, compared to when titanium is not included.

### 1-5. Method for Manufacturing Piezoelectric Element 5

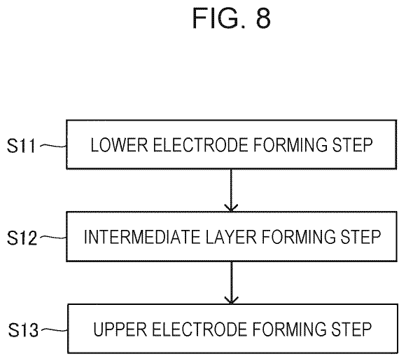

FIG. 8 is a diagram showing the flow of the method for manufacturing the piezoelectric element 5 of FIG. 6. As shown in FIG. 8, the method for manufacturing the piezoelectric element 5 includes a lower electrode forming step S11, an intermediate layer forming step S12, and an upper electrode forming step S13. These steps are performed in this order.

In the lower electrode forming step S11, the lower electrode 51 is formed. The lower electrode forming step S11 includes the formation of the first electrode layer 511 and the formation of the second electrode layer 512. Specifically, first, for example, a layer including a conductive material such as platinum is film-formed at the vibration plate 33 using a sputtering method, a vapor deposition method, or a Chemical Vapor Deposition (CVD) method to form the first electrode layer 511. Next, for example, a layer including a conductive material such as iridium is film-formed at the first electrode layer 511 using a sputtering method, a vapor deposition method, or a CVD method to form the second electrode layer 512.

The intermediate layer forming step S12 includes the formation of the third hydrogen absorbing layer 54, the formation of the piezoelectric layer 53, and the formation of the second hydrogen absorbing layer. Specifically, first, a layer including a hydrogen storage material such as titanium is film-formed at the lower electrode 51 using a sputtering method, a vapor deposition method, or a CVD method. Next, a first layer precursor formed of a perovskite-type complex oxide such as PZT is film-formed at the layer including the hydrogen storage material using the sol-gel method. Next, the layer including the hydrogen storage material and the first layer precursor are fired. As a result, the third hydrogen absorbing layer 54 and the first layer 531 are formed.

Next, another layer including a hydrogen storage material such as titanium is film-formed at the first layer 531 using a sputtering method, a vapor deposition method, or a CVD method. Next, a second layer precursor formed of a perovskite-type complex oxide such as PZT is film-formed at the other layer including the hydrogen storage material using the sol-gel method. Next, the other layer including the hydrogen storage material and the second layer precursor are fired. As a result, the fourth hydrogen absorbing layer 55 and the second layer 532 are formed.

When film-forming the fourth hydrogen absorbing layer 55, there is a concern that the fourth hydrogen absorbing layer 55 will be formed in a state where moisture remains on the surface of the first layer 531. For this reason, a heating step is preferably performed to remove moisture from the surface when forming the fourth hydrogen absorbing layer 55. Due to this, it is possible to reduce the amount of moisture remaining on the surface of the first layer 531. For this reason, the amount of hydrogen absorbed by the fourth hydrogen absorbing layer 55 when forming the fourth hydrogen absorbing layer 55 is reduced, thus, it is possible for the fourth hydrogen absorbing layer 55 after formation to absorb sufficient hydrogen.

Next, a third layer precursor formed of a perovskite-type complex oxide such as PZT is film-formed at the second layer 532 using the sol-gel method, and then the third layer precursor is fired. Due to this, the third layer 533 is formed. The fourth layer 534, the fifth layer 535, and the sixth layer 536 are formed by the same method. Next, after the sixth layer 536 is formed, the third hydrogen absorbing layer 54, the fourth hydrogen absorbing layer 55, and the piezoelectric layer 53 are fired as a batch.

When each layer of the piezoelectric layer 53 is formed by sol-gel, the shape and crystallinity of the lower layer affect the shape and crystallinity of the upper layer. In the present embodiment, the hydrogen content of the second layer 532 is smaller than the hydrogen content of the third layer 533. For this reason, it is possible to suppress the shape and crystallinity of the second layer 532 from affecting the third layer 533 at the stage of film-forming the third layer 533, which is the middle layer portion of the piezoelectric layer 53, by sol-gel.

In the upper electrode forming step S13, the upper electrode 52 is formed. The upper electrode forming step S13 includes the formation of the third electrode layer 521, the formation of the second hydrogen absorbing layer 522, the formation of the electrode layer 523, and the formation of the first hydrogen absorbing layer 524. Specifically, for example, a layer including a conductive material such as iridium is film-formed at the sixth layer 536 by a sputtering method, a vapor deposition method, or a CVD method and then fired to form the third electrode layer 521 including a metal oxide or the like. Next, a layer including a conductive material such as titanium is film-formed at the third electrode layer 521 by a sputtering method, a vapor deposition method, or a CVD method and then fired to form the second hydrogen absorbing layer 522 including a metal oxide or the like.

Next, a layer including a conductive material such as iridium is film-formed at the second hydrogen absorbing layer 522 by a sputtering method, a vapor deposition method, or a CVD method to form the electrode layer 523. Next, a layer including a hydrogen storage material such as titanium is film-formed at the electrode layer 523 by a sputtering method, a vapor deposition method, or a CVD method to form the first hydrogen absorbing layer 524. Due to this, the piezoelectric element 5 is manufactured.

When film-forming the first hydrogen absorbing layer 524, there is a concern that the first hydrogen absorbing layer 524 may be formed in a state where moisture remains on the surface of the electrode layer 523. For this reason, a heating step is preferably performed to remove moisture from the surface when forming the first hydrogen absorbing layer 524. Due to this, it is possible to reduce the amount of moisture remaining on the surface of the electrode layer 523. For this reason, it is possible for the first hydrogen absorbing layer 524 after formation to absorb sufficient hydrogen.

### 2. Modified Examples

It is possible to modify the above-exemplified embodiments in various ways. Specific embodiments of modifications that are applicable to the above-described embodiments are shown below. It is possible to appropriately combine two or more embodiments selected from the following examples in a range that is not mutually contradictory.

### 2-1. First Modified Example

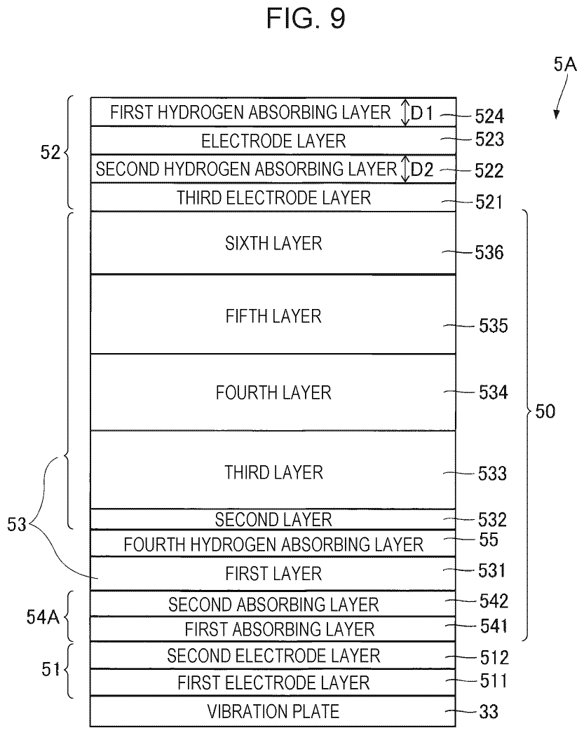

FIG. 9 is a diagram schematically showing a piezoelectric element 5A of a first modified example. As shown in FIG. 9, a third hydrogen absorbing layer 54A of the piezoelectric element 5A of the first modified example is formed of a plurality of layers having different constituent elements. Specifically, the third hydrogen absorbing layer 54A includes a first absorbing layer 541 and a second absorbing layer 542. The first absorbing layer 541 is formed of, for example, titanium. The second absorbing layer 542 is formed of, for example, lead zirconate (PbZrO₃) or lead titanate (PbTiO₃).

Forming the third hydrogen absorbing layer 54A from a plurality of layers makes it possible to more effectively suppress hydrogen from entering into the piezoelectric layer 53, compared to when formed from a single layer.

In addition, for the first absorbing layer 541 and the second absorbing layer 542, the hydrogen absorbing performances, that is, the amounts of hydrogen absorbed, may be different or the same. In addition, the second absorbing layer 542 may also function as the orientation control layer described above.

In the first embodiment and the first modified example, a part of the lower electrode 51 may be regarded as a part of the third hydrogen absorbing layer 54 and, in this case, the third hydrogen absorbing layer 54 may be regarded as being formed of a plurality of layers. For example, the second electrode layer 512 of the lower electrode 51 may be regarded as a part of the third hydrogen absorbing layer 54. In addition, the third hydrogen absorbing layer 54 may also function as an electrode.

### 2-2. Second Modified Example

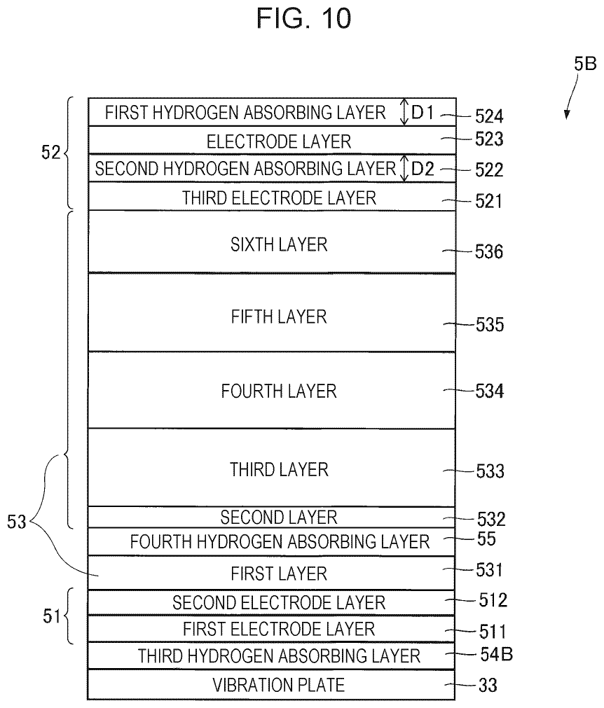

FIG. 10 is a diagram schematically showing a piezoelectric element 5B of the second modified example. As shown in FIG. 10, a third hydrogen absorbing layer 54B of the second modified example is provided below the lower electrode 51 in the direction along the Z-axis, which is the laminating direction. The third hydrogen absorbing layer 54B is arranged between the vibration plate 33 and the lower electrode 51 and is in contact therewith.

Arranging the third hydrogen absorbing layer 54B at a lower layer than the lower electrode 51 makes it possible to suppress hydrogen from entering into the piezoelectric layer 53 from the vibration plate 33 side.

### 2-3. Third Modified Example

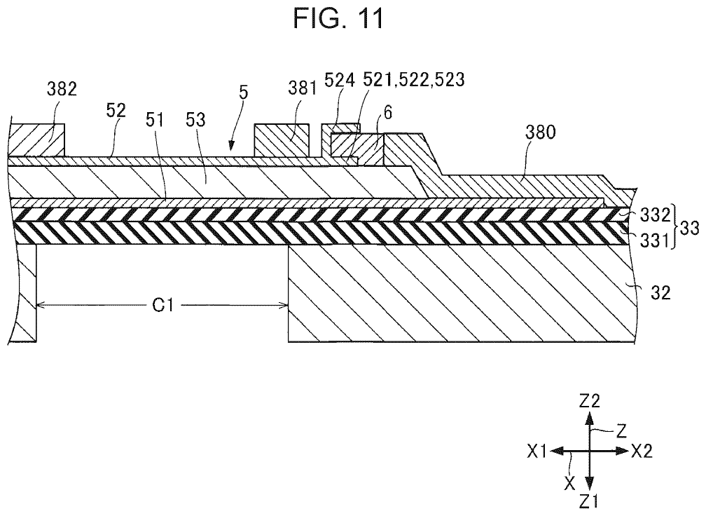

FIG. 11 is a cross-sectional diagram of the piezoelectric element 5 of a third modified example. As shown in FIG. 11, a protective film 6 is arranged on the upper surface of the piezoelectric layer 53. Specifically, the protective film 6 is arranged on one end portion of the piezoelectric layer 53 along the X-axis. A part of the upper surface of the piezoelectric layer 53 is not covered by the upper electrode 52 and is exposed. The protective film 6 is arranged on the exposed portion. The protective film 6 includes, for example, ceramics such as aluminum oxide (AlOx) and silicon nitride.

Providing the protective film 6 on the exposed portion of the piezoelectric layer 53 makes it possible to suppress hydrogen from entering into the piezoelectric layer 53. In addition, a part of the protective film 6 is interposed in the upper electrode 52. Specifically, the third electrode layer 521, the second hydrogen absorbing layer 522, and the electrode layer 523 are arranged below the protective film 6. The first hydrogen absorbing layer 524 is arranged above the protective film 6. Providing a part of the protective film 6 on the first hydrogen absorbing layer 524 makes it possible for the first hydrogen absorbing layer 524 to absorb hydrogen in the protective film 6 and to suppress the hydrogen in the protective film 6 from entering into the piezoelectric layer 53.

The first hydrogen absorbing layer 524 may be arranged below the protective film 6. In addition, the first hydrogen absorbing layer 524 is provided on a part of the upper surface of the protective film 6, but may be provided over the entire upper surface of the protective film 6.

In addition, when the protective film 6 is provided, in the method for manufacturing the piezoelectric element 5, the protective film 6 is formed after the third electrode layer 521, the second hydrogen absorbing layer 522, and the electrode layer 523 are formed and while the first hydrogen absorbing layer 524 is formed. The protective film 6 is mainly film-formed at the exposed portion of the upper surface of the piezoelectric layer 53 where the third electrode layer 521, the second hydrogen absorbing layer 522, and the electrode layer 523 are not provided. The protective film 6 is formed by film-forming a ceramic material using a sputtering method, a vapor deposition method, or a CVD method.

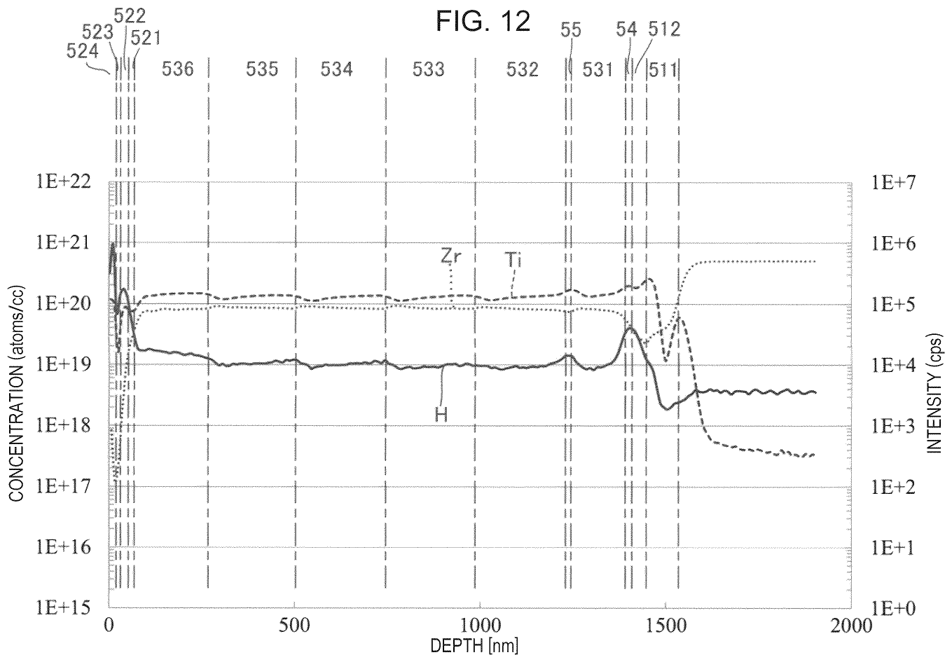

FIG. 12 is a diagram showing the measurement results of the piezoelectric element 5 of the third modified example using a secondary ion mass spectrometer. As is clear from FIG. 12, in this modified example, as in the first embodiment, the hydrogen content of the first hydrogen absorbing layer 524 is greater than the hydrogen content of the second hydrogen absorbing layer 522. The hydrogen content of the electrode layer 523 is smaller than each of the hydrogen contents of the first hydrogen absorbing layer 524 and the second hydrogen absorbing layer 522. The hydrogen content of the third electrode layer 521 is smaller than each of the hydrogen contents of the first hydrogen absorbing layer 524 and the second hydrogen absorbing layer 522. The hydrogen content of the first layer 531 is smaller than the hydrogen content of the second layer 532. In addition, the hydrogen content of the third hydrogen absorbing layer 54 is larger than the hydrogen content of the first layer 531. In addition, the hydrogen content of the fourth hydrogen absorbing layer 55 is smaller than the hydrogen content of the third hydrogen absorbing layer 54.

In addition, in the example of FIG. 12, the variation in the hydrogen content of the piezoelectric element 5 in the laminating direction at the central section is preferably 24% or less with respect to the average value.

### 2-4. Fourth Modified Example

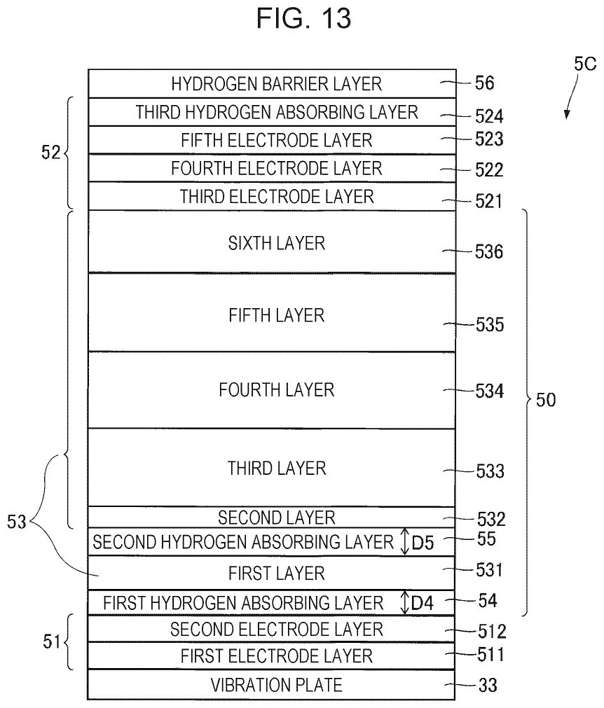

FIG. 13 is a diagram schematically showing a piezoelectric element 5C of a fourth modified example. As shown in FIG. 13, the piezoelectric element 5C of the fourth modified example has a hydrogen barrier layer 56 that suppresses hydrogen from entering into the uppermost layer in the laminating direction. The hydrogen barrier layer 56 includes, for example, ceramics such as aluminum oxide (AlOx) and silicon nitride. Providing the hydrogen barrier layer 56 makes it possible to suppress external hydrogen from entering into the piezoelectric layer 53, compared to when the hydrogen barrier layer 56 is not provided.

### 2-5. Other Modified Examples

The “liquid ejection head” may be a circulation type head having a so-called circulation flow path.

The “image forming device” may be adopted in various devices such as facsimile devices and copy machines, in addition to devices dedicated to printing. The use of the image forming device is not limited to printing. For example, image forming devices that eject a coloring material solution are used as manufacturing devices that form a color filter for display devices such as liquid crystal display panels. In addition, image forming devices that eject a solution of a conductive material are used as manufacturing devices that form wiring and electrodes of a wiring substrate. In addition, image forming devices that eject a solution of an organic substance related to a living body are used, for example, as manufacturing devices for manufacturing biochips.

The present disclosure was described above based on preferred embodiments, but the present disclosure is not limited to the above embodiments. In addition, it is possible to replace the configuration of each part of the present disclosure with any configuration that exerts the same function as the above embodiment, and to add any configuration.

What is claimed is:

1. A piezoelectric element comprising:
a lower electrode;
a piezoelectric layer formed of a perovskite-type complex oxide; and
an upper electrode having a first hydrogen absorbing layer, wherein
the lower electrode, the piezoelectric layer, and the upper electrode are laminated in a laminating direction, and
the upper electrode has a first hydrogen absorbing layer that absorbs hydrogen.

2. The piezoelectric element according to claim 1, wherein
the upper electrode has a second hydrogen absorbing layer different from the first hydrogen absorbing layer.

3. The piezoelectric element according to claim 2, wherein
a film thickness of the first hydrogen absorbing layer is thicker than a film thickness of the second hydrogen absorbing layer in the laminating direction.

4. The piezoelectric element according to claim 2, wherein
a hydrogen content of the first hydrogen absorbing layer is greater than a hydrogen content of the second hydrogen absorbing layer.

5. The piezoelectric element according to claim 2, wherein
the upper electrode has an electrode layer formed of a conductive material, and
the electrode layer is provided between the second hydrogen absorbing layer and the first hydrogen absorbing layer in the laminating direction.

6. The piezoelectric element according to claim 2, wherein
the upper electrode has an electrode layer formed of a conductive material, and
a hydrogen content of the electrode layer is smaller than the hydrogen content of the first hydrogen absorbing layer.

7. The piezoelectric element according to claim 1, wherein
the film thickness of the first hydrogen absorbing layer is 10 nm or more and 25 nm or less.

8. The piezoelectric element according to claim 1, wherein
the piezoelectric layer is formed of a plurality of layers, and
variation in a hydrogen content at a central section of the piezoelectric layer is 24% or less with respect to an average value.

9. The piezoelectric element according to claim 1, further comprising:
a protective film provided on the piezoelectric layer to protect the piezoelectric layer, wherein the first hydrogen absorbing layer is provided on the protective film.

10. The piezoelectric element according to claim 1, further comprising:
a third hydrogen absorbing layer that absorbs hydrogen provided between the piezoelectric layer and the lower electrode, or on the lower electrode.

11. The piezoelectric element according to claim 1, further comprising:
a hydrogen barrier layer that suppresses hydrogen from entering into an uppermost layer in the laminating direction.

12. A liquid ejection head comprising:
the piezoelectric element according to claim 1.
